(19) United States
(12) Patent Application Publication
(10) Pub. No.: US 2025/0068086 A1
(43) Pub. Date: Feb. 27, 2025

(54) MASKLESS PHOTOLITHOGRAPHY PROCESS FOR THE SYNTHESIS OF METALLIC NANOSTRUCTURES OF FRACTAL GEOMETRY DIRECTLY ON 2D PRINTED CARBON-BASED NANOSHEETS UNDER ROOM TEMPERATURE UV IRRADIATION

(71) Applicant: Qatar Foundation for Education, Science and Community Development, Doha (QA)

(72) Inventors: Hicham Hamoudi, Doha (QA); Sara Iyad Mohd Saleh Ahmad, Doha (QA)

(21) Appl. No.: 18/813,454

(22) Filed: Aug. 23, 2024

Related U.S. Application Data
(60) Provisional application No. 63/534,672, filed on Aug. 25, 2023.

(51) Int. Cl. G03F 7/00; B33Y 40/20; B33Y 70/10; B33Y 80/00; G03F 7/20; H01L 21/04

(52) U.S. Cl. CPC G03F 7/70383; B33Y 40/20; B33Y 70/10; B33Y 80/00; G03F 7/2051; G03F 7/2059; H01L 21/0425

(57) ABSTRACT

A maskless photolithography technique is provided for the direct synthesis and integration of metallic nanostructures exhibiting branching and flower-like fractal geometries on two-dimensional (2D) carbon-based nanosheets, employing room temperature ultraviolet (UV) irradiation. The photolithography process leverages the structural and electronic properties of carbon-based nanosheets comprising semiconducting organic carbon-based molecular monolayers connected by metallic atoms providing strong covalent linkages. By embedding the metallic precursor for fractal nanostructures within the carbon-based nanosheet during the initial synthesis, UV irradiation initiates the photoreduction of metallic atoms and their growth into fractal nanostructures with high yield and uniformity.

### CROSS-REFERENCE TO RELATED APPLICATION

The present disclosure claims priority to U.S. Provisional Patent Application 63/534,672 having a filing date of Aug. 25, 2023, the entirety of which is incorporated herein.

### BACKGROUND

Invented in the 1800s to create prints on stones, photolithography is a printing method in which light-matter interactions can develop topographically patterned surfaces with sub-micrometer resolution. Propelled by the technological progress in optical exposure systems, photoresistor materials, and processing procedures, advanced photolithography techniques have emerged as the frontrunner alongside the semiconductor industry. However, beyond integrated circuits manufacturing, photolithography processes also have a host of applications in industries such as microelectronics, photonics, optics, energy harvesting, biotechnology, and medicine.

Generally, UV light is used to transfer specific patterns from a mask onto a light-sensitive material or a photoresistor that is coated on the desired substrate. High energy photons from a selected or focused UV light induce physical and chemical changes in the light-sensitive photoresistor and subsequently cause the UV exposed areas to either break down or harden. The patterned photoresistor film can then be treated by chemicals to remove the softer unaffected areas in the film, which is followed by substrate etching and metal deposition steps to finally create the desired microchip.

Fueled by the progressive demands for further miniaturization and higher resolution printing for the development of the next generation information and communication technologies, modern maskless techniques have been introduced beyond the traditional multi-step (mask-wise), complex, time consuming, and expensive conventional photolithography. Such processes include interference photolithography which makes use of the periodic patterns obtained from the interference of two or more laser coherent beams through controlling their angles and phase differences to create well-defined periodic patterns on films and substrates. Light-assisted direct writing techniques such as stereolithography and digital light processing have also emerged as modern photolithographic techniques that can transfer computer-aided designs into complex and tangible structures by directly scanning a focused laser beam on a photosensitive film that is placed on top of a computer-controlled motorized stage. However, these techniques may be limited by writing speed or lateral resolution. A different set of photolithography techniques has emerged where light is employed to set a structure created prior to irradiation rather than employing light irradiation to define the desired pattern or structure. Such techniques include UV assisted nanoimprinting lithography, and additive manufacturing three-dimensional (3D) printing techniques such as inkjet and extrusion-based 3D printing.

Photoirradiation using UV light has also long been used to in-situ synthesize metallic nanoparticles (NPs) reinforced polymer matrix composites. The typical technique for the in-situ synthesis of metallic NPs inside a solid polymer film includes mixing a polymer-based solution with a suitable metal precursor (metal salt or metal complex), followed by spinning or dipping coating procedures to create the hybrid metal/polymer film. Subsequently, the film is irradiated by UV light to reduce the metal ion precursor into metallic NPs and simultaneously cross link the polymers and create a solid hybrid composite film. The potential of photolithography to fabricate nanoparticle patterns through photomasking has been studied. Experiments are underway to use focused UV light to restrict and control the photoinduced transformations in the nanosheet and thus create more complex fractal designs and patterns.

The unique structural characteristics of metallic fractal assemblies has attracted scientific interest and opened innovative research directions for a wide variety of applications thanks to its inherent unique structure-property relationship. Fractal architecture provides highly desirable advantages such as a smart occupation of surface areas and the efficient transfer of electrical and chemical signals. The same fractal concept can be approached to design new fractal-based processor systems or solar cell structures and energy conversion devices. Recently, studies have emphasized the importance of adapting a fractal like-electrical network that mimics the fractal nature of biological neurons to enhance the communication of electrical signals from implants to neurons. Using lithographic methods for the reproduction of metallic fractal nanostructures has been challenging. One obstacle hindering successful utilization of fractal metallic electrodes in the next generation of electronic applications, despite their undebatable advantages, is the difficulty in both transferring and integrating those grown metallic nanostructures with other electronic circuit components.

### SUMMARY

The present disclosure relates to a novel method that utilizes UV radiation for the direct synthesis and integration of metallic fractal nanostructures on two-dimensional carbon-based organic nanosheets according to an embodiment.

According to one non-limiting aspect of the present disclosure, an example embodiment of the direct synthesis and integration of metallic nanostructures exhibiting branching and flower-like fractal geometries on two dimensional (2D) carbon-based nanosheets is provided. In one embodiment, the system includes a process to synthesize metallic nanostructures on carbon-based nanosheets.

In light of the disclosure herein and without limiting the disclosure in any way, in an aspect of the present disclosure, which may be combined with any other aspect listed herein unless specified otherwise, a maskless photolithography method for synthesis of metallic nanostructures with fractal geometries on three-dimensional (3D) printed two-dimensional (2D) carbon-based nanosheets using ultraviolet (UV) or electron irradiation.

In another aspect of the present disclosure, which may be combined with any other aspect listed herein unless specified otherwise, the 3D printed 2D carbon-based nanosheets include organic carbon-based molecular monolayers joined by metallic atoms.

In another aspect of the present disclosure, which may be combined with any other aspect listed herein unless specified otherwise, the method further comprises a covalent linkage between the organic carbon-based molecular monolayers and the metallic atoms.

In another aspect of the present disclosure, which may be combined with any other aspect listed herein unless specified otherwise, the metallic atoms are embedded in the carbon-based nanosheets during an initial 3D printed building-block synthesis process.

In another aspect of the present disclosure, which may be combined with any other aspect listed herein unless specified otherwise, the UV irradiation initiates a photoreduction of the metallic atoms.

In another aspect of the present disclosure, which may be combined with any other aspect listed herein unless specified otherwise, the photoreduction of the metallic atoms causes growth of the metallic nanostructures with fractal geometries.

In another aspect of the present disclosure, which may be combined with any other aspect listed herein unless specified otherwise, the UV irradiation cross-links the 3D printed 2D carbon-based nanosheets.

In another aspect of the present disclosure, which may be combined with any other aspect listed herein unless specified otherwise, the synthesis of metallic nanostructures includes a light-assisted technique.

In another aspect of the present disclosure, which may be combined with any other aspect listed herein unless specified otherwise, the metallic nanostructures are utilized in electrical circuits for a human implant, a solar cell, a fractal antenna, a unique identifier in supply chains, or a techno molecular application.

In another aspect of the present disclosure, which may be combined with any other aspect listed herein unless specified otherwise, a complete electronic circuit component is integrated with the fractal antenna to build one or both of an electronics device and an energy conversion device. In an embodiment, the complete electronic circuit component includes one or more of a diode, a capacitor, and a transistor. In an embodiment, the diode includes one or both of an organic diode and an inorganic diode, wherein the capacitor includes one or both of an organic capacitor and an inorganic capacitor, and wherein the transistor includes one or both of an organic transistor and an inorganic transistor.

In light of the disclosure herein and without limiting the disclosure in any way, in an aspect of the present disclosure, which may be combined with any other aspect listed herein unless specified otherwise, a maskless photolithography method comprising generating metallic nanostructures with fractal geometries directly on the three-dimensional (3D) printed carbon-based two-dimensional (2D) nanosheets, where metallic atoms are embedded into the nanosheets during a fabrication process using self-assembly molecular monolayers prior to an ultraviolet (UV) patterning process.

In another aspect of the present disclosure, which may be combined with any other aspect listed herein unless specified otherwise, the method further comprises combining a light-sensitive 3D printed hybrid metal and carbon nanosheet with UV irradiation.

In another aspect of the present disclosure, which may be combined with any other aspect listed herein unless specified otherwise, the method further comprises utilizing the metallic nanostructures to assemble an electronic device at a molecular level and in a bottom-up manner.

In another aspect of the present disclosure, which may be combined with any other aspect listed herein unless specified otherwise, the method further comprises creating high-throughput creation of nanoscale fractal nanostructures with a high-precision.

In another aspect of the present disclosure, which may be combined with any other aspect listed herein unless specified otherwise, the method further comprises integrating conductive fractal structures from a nano-length scale to a micro-length scale based on an irradiation condition including at least one of time or dose.

In another aspect of the present disclosure, which may be combined with any other aspect listed herein unless specified otherwise, the method is performed at a room temperature and an atmospheric condition.

In another aspect of the present disclosure, which may be combined with any other aspect listed herein unless specified otherwise, the method is template-free, solvent-free, surfactant and chemical-free, environmentally friendly, and does not require any subsequent steps to create or transform the metallic nanofractals.

In another aspect of the present disclosure, which may be combined with any other aspect listed herein unless specified otherwise, the method further comprises providing nanoscale resolution formation of metallic fractals on the nanosheets.

In another aspect of the present disclosure, which may be combined with any other aspect listed herein unless specified otherwise, at least one of an organic diode, an inorganic diode, a capacitor, and a transistor is integrated with the fractal antenna to build an electronic or energy conversion device.

Additional features and advantages are described herein, and will be apparent from the following Detailed Description and the figures.

### BRIEF DESCRIPTION OF THE FIGURES

Features and advantages of the present disclosure, including a process for the synthesis of metallic nanostructures of fractal geometry on carbon-based nanosheets under room temperature UV irradiation, described herein may be better understood by reference to the accompanying drawings in which:

FIG. 1 is an optical microscope image of a three-dimensional (3D) printed BPD-Ag nanosheet after UV exposure for one hour, according to an embodiment of the present disclosure.

FIG. 2 is a magnification of the optical microscopic image of FIG. 1, according to an embodiment of the present disclosure.

FIG. 3 is a Scanning Electron Microscope image of a 3D printed BPD-Ag nanosheet after UV exposure for one hour, according to an embodiment of the present disclosure.

FIG. 4 is a magnification of the Scanning Electron Microscope image of FIG. 3, according to an embodiment of the present disclosure.

Skilled artisans will appreciate that elements in the figures are illustrated for simplicity and clarity and have not necessarily been drawn to scale. For example, the dimensions of some of the elements in the figures may be exaggerated relative to other elements to help to improve understanding of embodiments of the present disclosure.

The apparatus and method components have been represented where appropriate by conventional symbols in the drawings, showing only those specific details that are pertinent to understanding the embodiments of the present disclosure so as not to obscure the present disclosure with details that will be readily apparent to those of ordinary skill in the art having the benefit of the description herein.

### DETAILED DESCRIPTION

According to an embodiment, the present disclosure is generally related to a process to synthesize metallic nanostructures on carbon-based nanosheets. Specifically, the present disclosure relates to a maskless photolithography method for the synthesis of metallic nanostructures with fractal geometries on three-dimensional (3D) printed two-dimensional (2D) carbon-based nanosheets using ultraviolet (UV) irradiation.

The present disclosure relates to a new direct UV-irradiation method for the synthesis of metallic fractal nanostructures and its direct integration in organic carbon-based nanosheets according to an embodiment. The combination of the unique 3D printed hybrid metal-organic nanosheets and the ability of light to trigger specific physicochemical changes in the nanosheet by simple exposure to produce well-defined conductive metallic fractal nanostructures and its direct integration in organic nanosheets is a pivotal point behind the present technology according to an embodiment.

Compared to other lithographic techniques for the fabrication of conductive fractal nanostructures, the disclosed process utilizes (i) UV irradiation on hybrid metal/carbon-based nanosheets synthesized using a 3D printing approach based on the molecular self-assembly concept, (ii) a metal precursor (metallic atoms) for the fractal nanostructures is embedded in the hybrid metal/carbon-based nanosheets during the initial synthesis, (iii) the 3D printed nanosheet which acts as both the substrate and the active material on which the fractal formation is to take place, as well as the source of the metallic fractals to be formed, (iv) metallic pattern creation which is done directly in one step without the need of chemicals, photoresists, additional lift-off or metal deposition steps to create or transform the metallic patterns, and (v) the incorporation of the grown metallic fractal nanostructures onto the 2D organic molecular carbon-based nanosheet which enables the assembly of nanoscale electronic circuits for the next generation flexible, molecular electronics, energy harvesting, biomedical, and technorganic applications. This approach for the direct synthesis and integration of electrically conductive nanostructures on semiconducting organic nanosheets through light-assisted techniques has the potential to revolutionize the microelectronics industry, enabling flexible miniaturized electrical components and circuits for applications in human implants, solar cells, fractal antennas, unique identifiers in supply chains, and next-generation of techno molecular applications. In such applications, complete electronic circuit components, such as organic and inorganic diodes, capacitors, and transistors can integrate with fractal antennas to build various electronics and/or energy conversion devices.

Initially, the hybrid metal/carbon-based nanosheets are synthesized by a simple molecular-building block 3D printing process. In this process, metallic atoms are used as mediators to strategically join the organic carbon-based molecular monolayers together forming a periodic and continuous carbon-metal structured nanosheet. Thus, the metallic precursor for the formation of metallic nanostructures is already embedded in the carbon-based nanosheet during the initial building block synthesis process. Light-matter interactions are known to produce photochemical and photophysical changes that otherwise do not occur at ambient conditions. Upon exposing the nanosheet to UV irradiation, the high energy UV photons excite the irradiated molecules and initiate the photoreduction of the embedded metallic atoms while the semiconducting nature of the self-assembled organic molecules that make up the nanosheet influence the growth of the reduced metallic atoms into fractal nanostructures. Furthermore, UV irradiation simultaneously cross-links the carbon-based molecules resulting in a stable and strong metallically patterned nanosheet.

The present disclosure relates to a maskless photolithography method for the synthesis of metallic nanostructures with fractal geometries on 3D printed two-dimensional (2D) carbon-based nanosheets using ultraviolet (UV) irradiation, providing nanoscale resolution formation of metallic fractals directly on carbon-based nanosheets. In some embodiments, the method is a one-step photolithography process. The method leverages the structural and electronic properties of carbon-based nanosheets comprising semiconducting organic carbon-based molecular monolayers connected by metallic atoms providing strong covalent linkages. The process for metallic fractal nanostructures is performed at room temperature atmospheric conditions. The method is template-free, solvent-free, surfactant and chemical-free, environmentally friendly, and does not require any subsequent steps to create or transform the metallic nanofractals.

The 3D printed 2D carbon-based nanosheets include organic carbon-based molecular monolayers held together by metallic atoms, providing covalent connections between the organic molecules.

The metallic precursor for the fractal nanostructures is embedded in the carbon-based nanosheet during an initial 3D printed building-block synthesis process. By embedding the metallic precursor for fractal nanostructures within the carbon-based nanosheet during the initial synthesis, UV irradiation initiates the photoreduction of metallic atoms and its growth into fractal nanostructures with high yield and uniformity. Concurrently, the carbon-based molecules are cross-linked, resulting in a stable and robust metallically patterned nanosheet. In other embodiments, the metallic precursors are already embedded into the molecular-based nanosheet during the fabrication process using the self-assembly molecular monolayers prior to the UV patterning process which allows for the UV activated formation of fractal metallic nanostructures and its incorporation in the simultaneously UV cross-linked semiconducting carbon-based nanosheets at the same time.

The direct synthesis of electrically conductive well-defined nanostructures and its simultaneous integration on semiconducting organic nanosheets is achieved through light-assisted techniques. The method combines a new generation of light-sensitive 3D printed hybrid metal/carbon nanosheets with UV irradiation. The UV irradiation initiates the photoreduction of the embedded metallic atoms and its growth into fractal nanostructures with high yield and good uniformity. Simultaneously, the UV irradiation cross-links the 3D printed carbon-based molecules, resulting in a stable and strong metallically patterned nanosheet. In alternative embodiments, electron irradiation may be utilized instead of UV irradiation.

For the proof-of-concept experiments, the 3D printing method was used to synthesize the hybrid organic metal-containing carbon-based nanosheet using dithiol-PBD molecules and silver ions (Ag+) as the carbon backbone and the metal precursor, respectively. The nano-thin sheet was then placed directly on a conductive gold coated silicon substrate. Since the used UV-crosslinker illuminates light on the nanosheet, transmission electron microscope (TEM) Cu grids with a rectangular mesh were placed on top of the nanosheet to trace the effect of UV irradiation, create patterned illumination, and control where the photoinduced transformation occurs. The nanosheet was then inserted in a UV-crosslinker chamber where the UV irradiation took place for one hour at 100,000 dose.

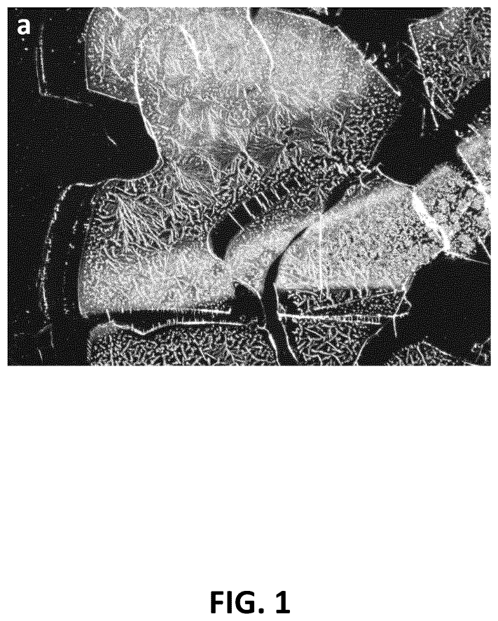

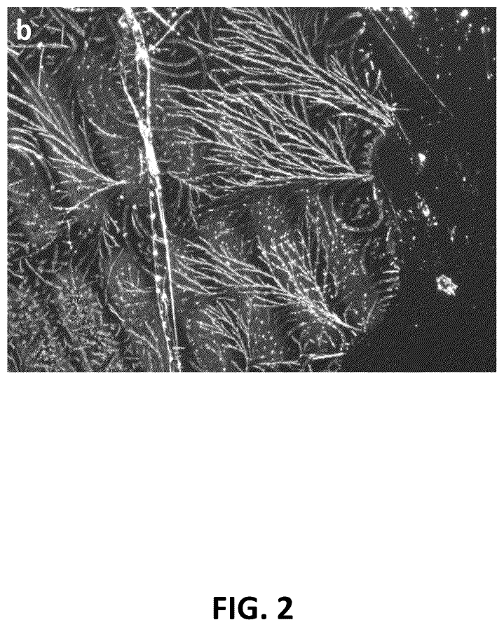

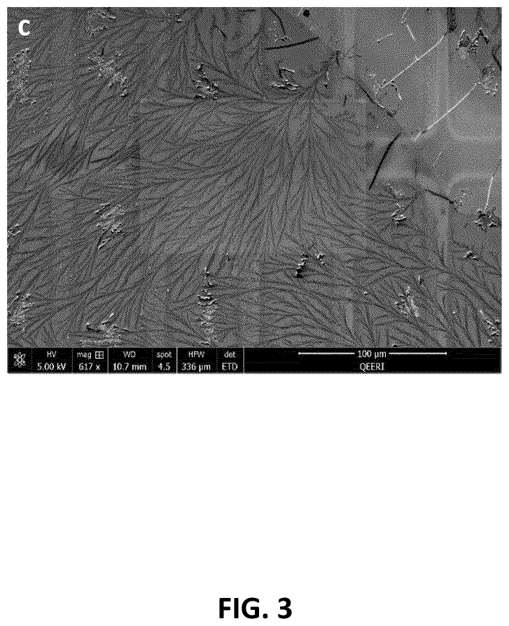

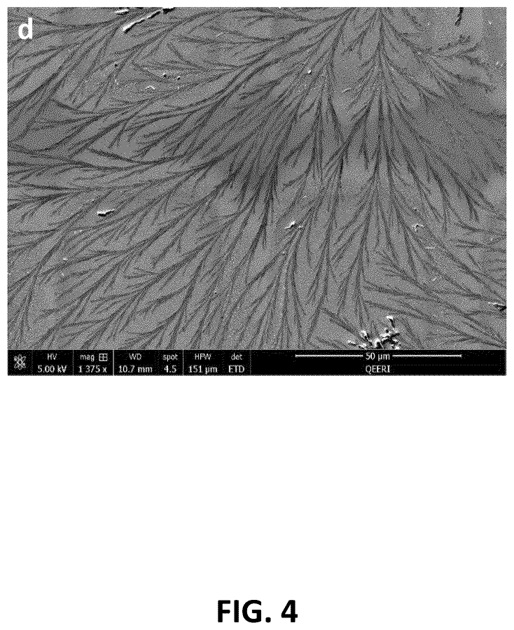

A sequence of optical microscope and scanning electron microscope (SEM) images showing the metallic fractal nanostructures formation and growth path on the carbon-based nanosheet can be seen in FIGS. 1-4. FIG. 1 illustrates an optical microscope image of a 3D printed BPD-Ag nanosheet after UV exposure for one hour, while FIG. 2 is a magnification of FIG. 1. FIG. 3 is a Scanning Electron Microscope image of a 3D printed BPD-Ag nanosheet after UV exposure for one hour, while FIG. 4 is a magnification of FIG. 3.

FIGS. 2 and 4 are a magnified image of the fractal nanostructure confirming the nanometric nature and size of the formed fractal NPs. Most of the UV irradiation induced nano-metallic fractals consisted of long central metallic backbones and sharp secondary branches mimic a tree-like morphology. Otherwise, flower-like fractal nanostructures appeared with a center of a higher density connected to branches that extend from the center outward. In general, the photo-formed fractal nanostructures exhibit good symmetry and self-similarity.

Upon exposing the nanosheet to UV irradiation, the high energy UV photons excite the electrons of the irradiated molecules and initiate the photoreduction of the embedded metallic atoms while the excitation of the semiconducting self-assembled organic molecules that comprise the nanosheet influence the growth of the reduced metallic atoms into fractal nanostructures. Both theoretical and experimental studies have shown that the path pursued by electrons in semiconducting materials is one of fractal nature. The process of metallic fractal formation in the BPD nanosheet started with the electric discharge and propagation of excited electrons in a branching fractal pattern in an attempt to find the most conductive path. After, the branches of the metallic fractal patterns started to form and grow by the diffusion of the Ag+ ions onto the oppositely charged fractal path already created by the transport of discharged electrons in the nanosheet. Furthermore, UV irradiation simultaneously cross-links the carbon-based molecules resulting in a stable and strong metallically patterned nanosheet.

The ability to control physical and/or chemical changes to create smart lithographic conductive patterns with light in a remote fashion is a powerful concept. In the present disclosure, a next generation bottom-up nano-lithographic process where simple UV irradiation on a specially prepared 3D printed hybrid metal/organic nanosheet is disclosed. The process can result in the formation of conductive fractal nanostructure networks directly on the semiconducting nanosheets.

The proposed method has a number of advantages over existing lithographic processes for metallic fractal nanostructures synthesis, for example: (i) combining a new generation of light-sensitive (3D printed hybrid metal/carbon nanosheets) with UV irradiation; (ii) combining material architecture and function at different length scales and builds a new generation of devices with unmatched capabilities; (iii) developing electrically conductive well-defined fractal self-similar nano and microstructures through light-assisted technologies; (iv) providing room temperature atmospheric synthesis of metallic fractal nanostructures; (v) directly fabricating metallic fractal nanostructures on organic carbon-based nanosheets; (vi) including metallic precursor in the carbon-based sheet is done during the same synthesis process of the sheet itself; (vii) one-step metallic deposition/printing/writing of fractal nanostructures; (viii) providing an environmentally green solution without requiring any subsequent steps to create or transform the metallic nanofractals to template free, solvent free, surfactant free, and chemical free; (ix) forming metallic fractals directly on carbon-based nanosheets at a nanoscale resolution; (x) integrating metallic fractal nanostructures and the carbon-based nanosheet which provides the ability to assemble electronic devices at a molecular level and a bottom-up manner; (xi) creating nanoscale fractal nanostructures at a high-throughput with high-precision; (xii) providing the ability to assemble electronic devices at a molecular level and in a bottom-up manner; and (xiii) the ability to integrate conductive fractal structures across different length scales, from nano to microscale based on irradiation conditions (time, dose, etc.).

It should be understood that various changes and modifications to the presently preferred embodiments described herein will be apparent to those skilled in the art. Such changes and modifications can be made without departing from the spirit and scope of the present subject matter and without diminishing its intended advantages. It is therefore intended that such changes and modifications be covered by the appended claims.

The invention is claimed as follows:

1. A maskless photolithography method for synthesis of metallic nanostructures with fractal geometries on three-dimensional (3D) printed two-dimensional (2D) carbon-based nanosheets using an ultraviolet (UV) or an electron irradiation.

2. The method of claim 1, wherein the 3D printed 2D carbon-based nanosheets include organic carbon-based molecular monolayers joined by metallic atoms.

3. The method of claim 2, further comprising a covalent linkage between the organic carbon-based molecular monolayers and the metallic atoms.

4. The method of claim 2, wherein the metallic atoms are embedded in the carbon-based nanosheets during an initial 3D printed building-block synthesis process.

5. The method of claim 2, wherein the UV irradiation initiates a photoreduction of the metallic atoms.

6. The method of claim 5, wherein the photoreduction of the metallic atoms causes growth of the metallic nanostructures with fractal geometries.

7. The method of claim 1, wherein the UV irradiation cross-links the 3D printed 2D carbon-based nanosheets.

8. The method of claim 1, wherein the synthesis of metallic nanostructures includes a light-assisted technique.

9. The method of claim 1, wherein the metallic nanostructures are utilized in an electrical circuit for a human implant, a solar cell, a fractal antenna, a unique identifier in a supply chains, or a techno molecular application.

10. The method of claim 9, wherein a complete electronic circuit component is integrated with the fractal antenna to build one or both of an electronic device and an energy conversion device.

11. The method of claim 10, wherein the complete electronic circuit component includes one or more of a diode, a capacitor, and a transistor.

12. The method of claim 11, wherein the diode includes one or both of an organic diode and an inorganic diode, wherein the capacitor includes one or both of an organic capacitor and an inorganic capacitor, and wherein the transistor includes one or both of an organic transistor and an inorganic transistor.

13. A maskless photolithography method comprising generating metallic nanostructures with fractal geometries directly on three-dimensional (3D) printed carbon-based two-dimensional (2D) nanosheets, wherein metallic atoms are embedded into the nanosheets during a fabrication process using self-assembly molecular monolayers prior to an ultraviolet (UV) patterning process.

14. The method of claim 10, further comprising combining a light-sensitive 3D printed hybrid metal and carbon nanosheet with UV irradiation.

15. The method of claim 10, further comprising utilizing the metallic nanostructures to assemble an electronic device at a molecular level and in a bottom-up manner.

16. The method of claim 10, further comprising creating nanoscale fractal nanostructures at a high-throughput and with a high-precision.

17. The method of claim 10, further comprising integrating conductive fractal structures from a nano-length scale to a micro-length scale based on an irradiation condition including at least one of time or dose.

18. The method of claim 10, wherein the method is performed at a room temperature and an atmospheric condition.

19. The method of claim 10, wherein the method is template-free, solvent-free, surfactant and chemical-free, environmentally friendly, and does not require a subsequent step to create or transform the metallic nanostructures.

20. The method of claim 10, further comprising providing nanoscale resolution formation of the metallic nanostructures on the nanosheets.
